(19) United States
(12) Patent Application Publication
(10) Pub. No.: US 2025/0218529 A1
(43) Pub. Date: Jul. 3, 2025

(54) MEMORY DEVICE INCLUDING STRUCTURE SHIELDING BITLINE AND METHOD OF CONTROLLING SHIELD VOLTAGE THEREOF

(71) Applicant: SAMSUNG ELECTRONICS CO., LTD., Suwon-si (KR)

(72) Inventors: HYUN-CHUL YOON, Suwon-si (KR); JEONGDON IHM, Suwon-si (KR); YOUNG SEOK PARK, Suwon-si (KR); DONGHAK SHIN, Suwon-si (KR)

(73) Assignee: SAMSUNG ELECTRONICS CO., LTD., Suwon-si (KR)

(21) Appl. No.: 19/003,208

(22) Filed: Dec. 27, 2024

(30) Foreign Application Priority Data
Dec. 28, 2023 (KR) 10-2023-0193771

(51) Int. Cl. G11C 29/56

(52) U.S. Cl. CPC G11C 29/56016; G11C 29/56004; G11C 29/56012

(57) ABSTRACT

A memory device includes: a memory cell array including a plurality of memory cells; bitlines connected to the plurality of memory cells; shield lines, each being arranged between the bitlines; and a shield line control circuit configured to control a timing of supplying a shield voltage to the shield lines based on a command received from an outside of the memory device.

### CROSS-REFERENCE TO RELATED APPLICATIONS

This application claims priority under 35 U.S.C. § 119 to Korean Patent Application No. 10-2023-0193771, filed on Dec. 28, 2023, in the Korean Intellectual Property Office, the disclosures of which are incorporated by reference herein in their entireties.

### BACKGROUND

### 1. Field

Example embodiments of the present disclosure relate to a semiconductor memory device, and more particularly, relate to a memory device including a bitline shield structure and a method of controlling the shield voltage thereof.

### 2. Description of Related Art

A semiconductor memory may be mainly classified as a volatile memory or a non-volatile memory. Read and write speeds of the volatile memory, for example, a dynamic random access memory (DRAM) or a static random access memory (SRAM) are fast, but data stored in the volatile memory disappear when a power is turned off. In contrast, the non-volatile memory may retain data even when the power is turned off. Therefore, the non-volatile memory may be used to store contents that must be preserved regardless of whether power is supplied or not.

A representative example of a volatile memory device is a DRAM. A memory cell of a volatile memory device may include a single N-type transistor, serving as a switch, and a single capacitor storing electric charges DATA. Binary information “1” or “0” may correspond to the presence or absence of the electric charges stored in the capacitor in the memory cell, for example, whether a terminal voltage of a cell capacitor is high or low. The memory cell may be connected to a wordline and a bitline. The bitline may be connected to a sense amplifier. The sense amplifier may sense data, stored in the memory cell, through the bitline based on a voltage applied to the wordline.

The volatile memory device may include a plurality of memory cells. The plurality of memory cells may be connected through a plurality of bitlines. However, as a way to increase a capacity of the volatile memory device, more memory cells are included in a limited space, and a size of each of the memory cells is also becoming smaller. Because of this, spacing between the bitlines is also reduced, and coupling may occur between the bitlines. When coupling occurs between the bitlines, an error may occur during a read operation.

### SUMMARY

Example embodiments of the present disclosure provide a memory device including shield lines arranged between bitlines and supplying a shield voltage to the shield lines at a specified timing according to operation modes of the memory device.

According to one or more example embodiments, there is provided a memory device including: a memory cell array including a plurality of memory cells; bitlines connected to the plurality of memory cells; shield lines, each being arranged between the bitlines; and a shield line control circuit configured to control a timing of supplying a shield voltage to the shield lines based on a command received from an outside of the memory device.

According to one or more example embodiments, there is provided a memory device including: a memory cell array including a plurality of memory cells; bitlines connected to the plurality of memory cells; shield lines, each being arranged between the bitlines; and a shield line control circuit configured to control a timing of supplying a shield voltage to the shield lines based on whether an electrical bridge between one of the bitlines and one of the shield lines is detected.

According to one or more example embodiments, there is provided a method of controlling a shield voltage of a memory device, the method including: detecting an occurrence of an electrical bridge between bitlines, connected to a plurality of memory cells, and shield lines, each being disposed between the bitlines; in response to detecting the occurrence of the electrical bridge, detecting an operation mode based on a command received from an outside of a memory device; determining a timing of supplying a shield voltage to the shield lines based on the operation mode; and providing the shield voltage to the shield lines based on the determined timing.

### BRIEF DESCRIPTION OF DRAWINGS

The above and other objects and features of the present disclosure will become apparent by describing in detail example embodiments thereof with reference to the accompanying drawings.

FIG. 1 is a block diagram illustrating a memory system according to one or more example embodiments.

FIG. 2 is a block diagram illustrating an example of a configuration of a memory device of FIG. 1.

FIG. 3 is a diagram illustrating an example of bitlines and shield lines of FIG. 2.

FIG. 4 is a diagram illustrating an example of a shield line control circuit of FIG. 2.

FIG. 5 is a timing diagram illustrating a bitline shield method according to one or more example embodiments.

FIG. 6 is a timing diagram illustrating a bitline shield method according to one or more example embodiments.

FIG. 7 is a timing diagram illustrating a bitline shield method according to one or more example embodiments.

FIG. 8 is a flowchart illustrating a method of controlling a shield voltage of a shield line according to one or more example embodiments.

FIG. 9 is a diagram illustrating another example of bitlines and shield lines of FIG. 2.

FIG. 10 is a diagram illustrating another example of a shield line control circuit of FIG. 2.

FIG. 11 is a timing diagram illustrating an example of a bitline shielding method using a shield line control circuit of FIG. 10.

FIG. 12 is a timing diagram illustrating another example of a bitline shielding method using a shield line control circuit of FIG. 10.

FIG. 13 is a timing diagram illustrating another example of a bitline shielding method using a shield line control circuit of FIG. 10.

FIG. 14 is a flowchart illustrating a method of controlling a shield voltage of a shield line according to one or more example embodiments.

### DETAILED DESCRIPTION

Below, example embodiments of the present disclosure will be described in detail and clearly to such an extent that an ordinary one in the art easily implements the inventive concepts.

Below, a dynamic random access memory (DRAM) will be used as an example for illustrating features and functions of the present disclosure. However, other features and performances may be easily understood by a person of ordinary skill in the art from information disclosed herein. The present disclosure may be implemented by other example embodiments or applied thereto. Further, the detailed description may be modified or changed according to viewpoints and applications without departing from the scope, spirit, and other objects of the present disclosure.

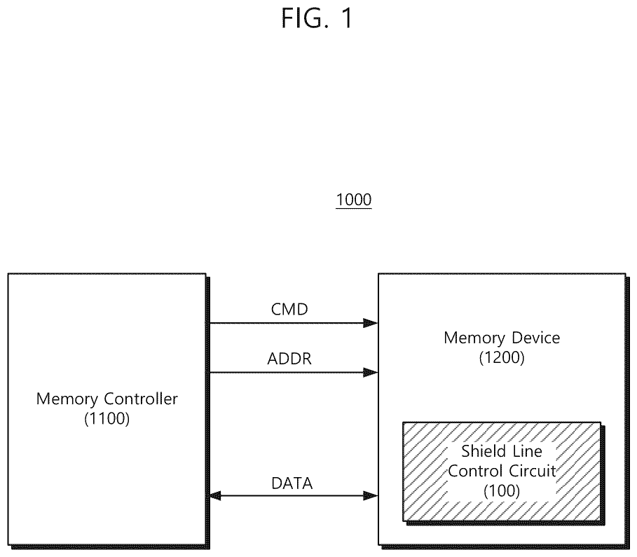

FIG. 1 is a block diagram illustrating a memory system according to one or more example embodiments. Referring to FIG. 1, a memory system 1000 may include a memory controller 1100 and a memory device 1200.

According to one or more example embodiments, the memory controller 1100 may perform an access operation of writing data to the memory device 1200 or reading data stored in the memory device 1200. For example, the memory controller 1100 may generate a command CMD and an address ADDR for writing data to the memory device 1200 or reading data stored in the memory device 1200. The memory controller 1100 may include at least one of a control circuit configured to control the memory device 1200, a system-on-chip (SoC) such as an application processor (AP), a central processing unit (CPU), a digital signal processor (DSP), and a graphics processing unit (GPU).

According to one or more example embodiments, the memory controller 1100 may provide various signals to the memory device 1200 to control an overall operation of the memory device 1200. For example, the memory controller 1100 may control memory access operations of the memory device 1200 such as a read operation and a write operation. The memory controller 1100 may provide the command CMD and the address ADDR to the memory device 1200 to write data DATA in the memory device 1200 or to read data DATA from the memory device 1200.

According to one or more example embodiments, the memory controller 1100 may generate various types of commands CMD to control the memory device 1200. For example, the memory controller 1100 may generate a bank request corresponding to a bank operation of changing a state of a memory bank, among memory banks, to read or write data DATA.

As an example, the bank request may include an active request for changing a state of a memory bank, among the memory banks, to an active state. The memory device 1200 may activate a row included in the memory bank, for example, a wordline, in response to the active request. The bank request may include a precharge request for changing the memory banks from an active state to a standby state after reading or writing of data DATA is completed.

In addition, the memory controller 1100 may generate an input/output (I/O) request (for example, a column address strobe (CAS) request) for the memory device 1200 to perform a read operation or a write operation of data DATA. As an example, the I/O request may include a read request for reading data DATA from activated memory banks. The I/O request may include a write request for writing data DATA in the activated memory banks.

Furthermore, the memory controller 1100 may generate a refresh command to control a refresh operation on the memory banks. However, the types of commands CMD described herein are merely examples, and other types of commands CMD may be present.

According to one or more example embodiments, the memory device 1200 may output data DATA, requested to be read by the memory controller 1100, to the memory controller 1100 or may store data DATA, requested to be written by the memory controller 1100, in a memory cell of the memory device 1200. The memory device 1200 may input and output data DATA based on the command CMD and the address ADDR. The memory device 1200 may include memory banks.

The memory device 1200 may be a volatile memory device such as a dynamic random access memory (DRAM), a synchronous dynamic random access memory (SDRAM), a double data rate (DDR) DRAM, a DDR SDRAM, a low-power double data rate (LPDDR) SDRAM, a graphics double data rate (GDDR) SDRAM, a Rambus dynamic random access memory (RDRAM), and a static random access memory (SRAM), or the like. Alternatively, the memory device 1200 may be implemented as a nonvolatile memory device such as a resistive RAM (RRAM), a phase change RAM (PRAM), a magnetoresistive RAM (MRAM), a ferroelectric RAM (FRAM), a spin-transfer torque RAM (STT-RAM), or the like. In the present specification, aspects and advantages of the present disclosure have been described with respect to a DRAM for illustrative purposes, but example embodiments are not limited thereto.

According to one or more example embodiments, the memory banks may include a memory cell array divided in units of banks, a row decoder, a column decoder, a sense amplifier, a write driver, or the like. The memory banks may store data DATA, requested to be written in the memory device 1200, through the write driver and may read data DATA, requested to be read, using the sense amplifier. The memory banks may further include a component for a refresh operation of storing and maintaining data in the cell array, or select circuits based on an address.

According to one or more example embodiments, memory cells included in the memory device 1200 may be connected to bitlines. To prevent coupling between the bitlines, the memory device 1200 may include shield lines disposed between the bitlines. The memory device 1200 may include a shield line control circuit 100 which applies a shield voltage to the shield lines. The shield line control circuit 100 may control the timing of supplying the shield voltage to the shield lines according to operation modes of the memory device 1200 to prevent coupling between the bitlines during operations of the memory device 1200.

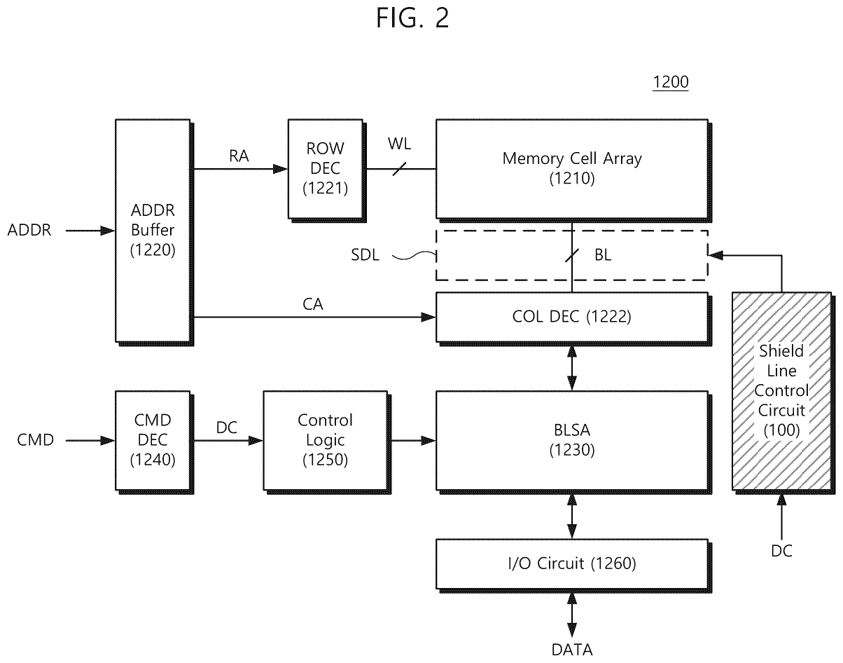

FIG. 2 is a block diagram illustrating an example of a configuration of a memory device of FIG. 1. Referring to FIG. 2, the memory device 1200 may include a memory cell array 1210, an address buffer 1220, a row decoder 1221, a column decoder 1222, a bitline sense amplifier 1230, a command decoder 1240, control logic 1250 and an input/output circuit 1260. In addition, the memory device 1200 may include a shield line control circuit 100.

According to one or more example embodiments, the memory cell array 1210 may include a plurality of memory cells arranged in a matrix of rows and columns. For example, the memory cell array 1210 may include a plurality of wordlines WL and a plurality of bitlines BL connected to memory cells. The plurality of wordlines WL may be connected to rows of the memory cells, and the plurality of bitlines BL may be connected to columns of the memory cells.

According to one or more example embodiments, the address buffer 1220 may receive an address ADDR from the memory controller 1100 of FIG. 1. For example, the address ADDR may include a row address RA addressing a row of the memory cell array 1210 and a column address CA addressing a column of the memory cell array 1210. The address buffer 1220 may transmit the row address RA to the row decoder 1221 and may transmit the column address CA to the column decoder 1222.

According to one or more example embodiments, the row decoder 1221 may select one of the plurality of wordlines WL connected to the memory cell array 1210. The row decoder 1221 may decode the row address RA, received from the address buffer 1220, to select a single wordline corresponding to the row address RA and may activate the selected wordline.

According to one or more example embodiments, the column decoder 1222 may select a bitline from among the plurality of bitlines BL of the memory cell array 1210. The column decoder 1222 may decode the column address CA, received from the address buffer 1220, to select the bitline BL corresponding to the column address CA.

According to one or more example embodiments, the bitline sense amplifier 1230 may be connected to the bitlines BL of the memory cell array 1210. For example, the bitline sense amplifier 1230 may sense a change in a voltage of a selected bitline, among the plurality of bitlines BL, and may amplify and output the change in the voltage.

According to one or more example embodiments, the command decoder 1240 may decode a write enable signal/WE, a row address strobe signal/RAS, a column address strobe signal/CAS, and a chip select signal/CS received from the memory controller 1100 such that control signals corresponding to the command CMD are generated in the control logic 1250. The command CMD may include an active request, a read request, a write request, and/or a precharge request.

The control logic 1250 may control an overall operation of the bitline sense amplifier 1230 through the control signals corresponding to the command CMD. The control logic 1250 may generate control signals such that the bitline sense amplifier 1230 operates as a single-ended sense amplifier. Additionally, the control logic 1250 may control an overall operation of the memory device 1200.

According to one or more example embodiments, the input/output circuit 1260 may output data DATA to the memory controller 1100 through data pad based on a sensed and amplified voltage from the bitline sense amplifier 1230. For example, the input/output circuit 1260 may include an input buffer and/or an output buffer. The input buffer and/or the output buffer may be connected to the data pad. The input/output circuit 1260 may perform a serialization operation and/or a deserialization operation of data DATA.

According to one or more example embodiments, the shield line control circuit 100 may apply a specified voltage to shield lines SDL. For example, each of the shield lines SDL may be disposed between the bitlines BL. To prevent coupling between the bitlines BL, the shield line control circuit 100 may apply a shield voltage to the shield lines SDL. The shield line control circuit 100 may control a timing of supplying the shield voltage to the shield lines SDL according to operation modes of the memory device 1200 to prevent coupling between the bitlines BL during operations of the memory device 1200.

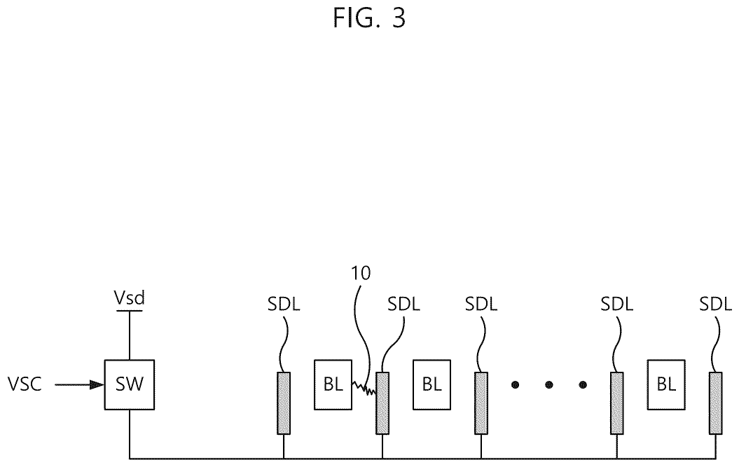

FIG. 3 is a diagram illustrating an example of bitlines and shield lines of FIG. 2. Referring to FIGS. 2 and 3, bitlines BL may be connected to the memory cell array 1210. Each of shield lines SDL and each of the bitlines BL may be alternately arranged. That is, the shield lines SDL and the bitlines BL may be arranged in an alternating pattern. For example, the shield lines SDL and the bitlines BL may be interleaved. For example, at least one bitline BL may be arranged between two shield lines SDL. For example, the bitlines BL are arranged in a first direction, the shield lines SDL are arranged in the first direction, and the bitlines BL and the shield lines SDL alternatingly appear along the first direction.

According to one or more example embodiments, a shield voltage Vsd may be provided to the shield lines SDL through a switch SW. The switch SW may be turned on or off based on a shield voltage control signal (or control signal) VSC. The shield line control circuit 100 may check an operation mode of the memory device 1200 based on a decoded command signal DC and generate the shield voltage control signal VSC based on the operation mode of the memory device 1200.

According to one or more example embodiments, the shield voltage Vsd may be provided to the shield lines SDL to prevent coupling between the bitlines BL. The shield voltage Vsd may be set in various ways. As an example, the shield voltage Vsd may be set equal to a precharge voltage of the bitline BL. As another example, the shield voltage Vsd may be set to be different from the precharge voltage of the bitline BL.

However, when an electrical bridge 10 occurs due to a defect between one of the bitlines BL and one of the shield lines SDL, a leakage current may occur between one of the bitlines BL and one of the shield lines SDL. A leakage current may occur when a voltage difference occurs between one of the bitlines BL and one of the shield lines SDL. Accordingly, when the shield voltage Vsd is always provided to the shield lines SDL, the coupling between the bitlines BL may be prevented, but significant current consumption due to a leakage current may occur.

To avoid this problem, the shield line control circuit 100 may control a supply timing of the shield voltage Vsd. For example, the shield line control circuit 100 may check the operation mode of the memory device 1200 based on the decoded command signal DC. The shield line control circuit 100 may determine the timing of the shield voltage control signal VSC based on the operation mode of the memory device 1200. The switch SW may supply the shield voltage Vsd to the shield lines SDL at a specified timing based on the shield voltage control signal VSC. Accordingly, the coupling between the bitlines BL may be prevented, and the current leakage may be minimized when the electrical bridge 10 occurs between one of the bitlines BL and one of the shield lines SDL.

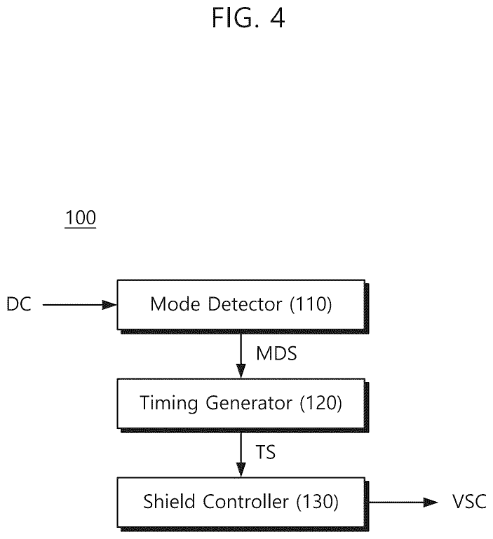

FIG. 4 is a diagram illustrating an example of a shield line control circuit of FIG. 2. Referring to FIGS. 2 to 4, the shield line control circuit 100 may include a mode detector 110, a timing generator 120, and/or a shield controller 130.

According to one or more example embodiments, the mode detector 110 may generate a mode detection signal (or mode signal) MDS indicating a current operation mode based on the decoded command signal DC. For example, the mode detector 110 may check a current operating state of the memory device 1200 based on the decoded command signal DC. As an example, the mode detector 110 may generate the mode detection signal MDS indicating whether the current operation mode is a precharge mode, a charge sharing mode, or a sensing mode. As another example, the mode detector 110 may generate the mode detection signal MDS indicating an active state of a selected wordline.

According to one or more example embodiments, the timing generator 120 may generate a timing signal TS based on the mode detection signal MDS. For example, the timing generator 120 may generate the timing signal TS including information about when the shield voltage Vsd will be supplied to the shield lines SDL.

According to one or more example embodiments, the shield controller 130 may generate the shield voltage control signal VSC based on the timing signal TS. For example, the shield controller 130 may generate the shield voltage control signal VSC which is used to control a turn-on or turn-off timing of the switch SW. As an example, the shield voltage control signal VSC may be generated such that the switch SW is turned on during a charge sharing mode. As another example, the shield voltage control signal VSC may be generated such that the switch SW is turned on while the selected wordline is active.

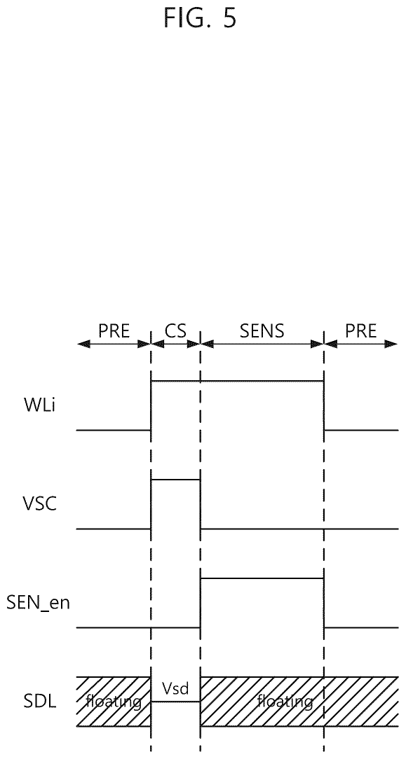

FIG. 5 is a timing diagram illustrating a bitline shield method according to one or more example embodiments. Referring to FIGS. 4 and 5, the memory device 1200 may repeatedly perform a precharge mode PRE, a charge sharing mode CS, and a sensing mode SENS during a read operation. In FIG. 5, a shield voltage Vsd may be set equal to a precharge voltage Vpre.

According to one or more example embodiments, in the precharge mode PRE, the bitlines BL may be charged with a specified precharge voltage Vpre. In the charge sharing mode CS, a selected wordline WLi may be activated and the bitlines BL may share charges (for example, data) stored in memory cells. In the sensing mode SENS, a sensing enable signal SEN_en may be activated and the bitline sense amplifier 1230 of FIG. 2 may detect a voltage of the bitlines BL and output data based thereon.

According to one or more example embodiments, the shield line control circuit 100 may activate the shield voltage control signal VSC during the charge sharing mode CS. For example, in the charge sharing mode CS, coupling may occur between the bitlines BL, and errors may occur in data due to the coupling between the bitlines BL. The shield line control circuit 100 may activate the shield voltage control signal VSC during the charge sharing mode CS and supply the shield voltage Vsd to the shield lines SDL. Accordingly, in the charge sharing mode CS, the coupling between the bitlines BL may be prevented.

According to one or more example embodiments, the shield line control circuit 100 may deactivate the shield voltage control signal VSC during the precharge mode PRE and the sensing mode SENS. For example, in the precharge mode PRE and the sensing mode SENS, the bitlines BL may be fixed to specified voltage(s), and the effect of coupling between the bitlines BL may be minimal. On the other hand, in the precharge mode PRE and the sensing mode SENS, when the electrical bridge 10 exists between one of the bitlines BL and one of the shield lines SDL and the shield voltage Vsd is supplied to the shield lines SDL, a leakage current may occur between one of the bitlines BL and one of the shield lines SDL. Accordingly, the shield line control circuit 100 may prevent a current leakage by floating the shield lines SDL during the precharge mode PRE and the sensing mode SENS.

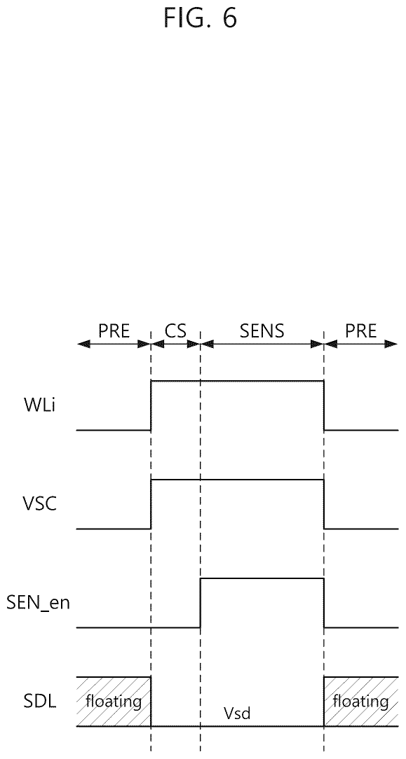

FIG. 6 is a timing diagram illustrating a bitline shield method according to one or more example embodiments. Referring to FIGS. 4 and 6, the memory device 1200 may repeatedly perform a precharge mode PRE, a charge sharing mode CS, and a sensing mode SENS during a read operation. In FIG. 6, a shield voltage Vsd may be set differently from a precharge voltage Vpre. For example, the shield voltage Vsd of FIG. 6 may be set lower than the shield voltage Vsd of FIG. 5.

According to one or more example embodiments, in the precharge mode PRE, the bitlines BL may be charged with a specified precharge voltage Vpre. In the charge sharing mode CS, a selected wordline WLi may be activated and the bitlines BL may share charges (for example, data) stored in memory cells. In the sensing mode SENS, a sensing enable signal SEN_en may be activated and the bitline sense amplifier 1230 of FIG. 2 may detect a voltage of the bitlines BL and output data based thereon.

According to one or more example embodiments, the shield line control circuit 100 may activate a shield voltage control signal VSC during the charge sharing mode CS and the sensing mode SENS. For example, in the charge sharing mode CS and the sensing mode SENS, coupling may occur between the bitlines BL and data errors may occur due to the coupling between the bitlines BL. The shield line control circuit 100 may activate the shield voltage control signal VSC during the charge sharing mode CS and the sensing mode SENS to supply the shield voltage Vsd to the shield lines SDL. Accordingly, in the charge sharing mode CS and the sensing mode SENS, the coupling between the bitlines BL may be prevented.

According to one or more example embodiments, the shield line control circuit 100 may deactivate the shield voltage control signal VSC during the precharge mode PRE. For example, in the precharge mode PRE, the bitlines BL may be fixed to specified voltage(s) and the effect of coupling between the bitlines BL may be minimal. On the other hand, in the precharge mode PRE, when the shield voltage Vsd is supplied to the shield lines SDL and the electrical bridge 10 exists between one of the bitlines BL and one of the shield lines SDL, a leakage current may occur between one of the bitlines BL and one of the shield lines SDL. Accordingly, the shield line control circuit 100 may prevent a current leakage by floating the shield lines SDL during the precharge mode PRE.

According to one or more example embodiments, the shield line control circuit 100 may activate the shield voltage control signal VSC while a selected wordline WLi is activated. For example, while the selected wordline WLi is activated, coupling may occur between the bitlines BL and data errors may occur due to the coupling between the bitlines BL. The shield line control circuit 100 may activate the shield voltage control signal VSC while the selected wordline WLi is activated and supply the shield voltage Vsd to the shield lines SDL. Accordingly, while the selected wordline WLi is activated, the coupling between the bitlines BL may be prevented.

According to one or more example embodiments, the shield line control circuit 100 may deactivate the shield voltage control signal VSC while the selected wordline WLi is deactivated. For example, while the selected wordline WLi is deactivated, the bitlines BL may be fixed to specified voltage(s) and the effect of coupling between the bitlines BL may be minimal. On the other hand, while the selected wordline WLi is deactivated, when the shield voltage Vsd is supplied to the shield lines SDL and the electrical bridge 10 exists between one of the bitlines BL and one of the shield lines SDL, a leakage current may occur between one of the bitlines BL and one of the shield lines SDL. Accordingly, the shield line control circuit 100 may prevent current leakage by floating the shield lines SDL while the selected wordline WLi is deactivated.

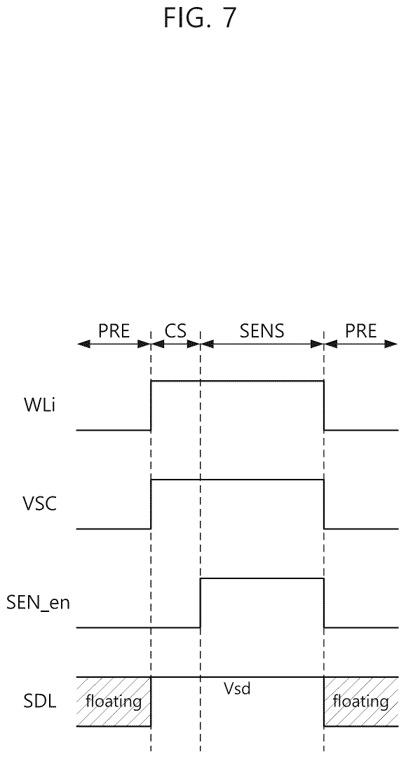

FIG. 7 is a timing diagram illustrating a bitline shield method according to one or more example embodiments. Referring to FIGS. 4 and 7, the memory device 1200 may repeatedly perform a precharge mode PRE, a charge sharing mode CS, and a sensing mode SENS during a read operation. In FIG. 7, a shield voltage Vsd may be set differently from a precharge voltage Vpre. For example, the shield voltage Vsd of FIG. 7 may be set higher than the shield voltage Vsd of FIG. 5.

According to one or more example embodiments, in the precharge mode PRE, the bitlines BL may be charged with a specified precharge voltage Vpre. In the charge sharing mode CS, a selected wordline WLi may be activated and the bitlines BL may share charges (for example, data) stored in memory cells. In the sensing mode SENS, the sensing enable signal SEN_en may be activated and the bitline sense amplifier 1230 of FIG. 2 may detect a voltage of the bitlines BL and output data based thereon.

According to one or more example embodiments, the shield line control circuit 100 may activate a shield voltage control signal VSC during the charge sharing mode CS and the sensing mode SENS. For example, in the charge sharing mode CS and the sensing mode SENS, coupling may occur between the bitlines BL and data errors may occur due to the coupling between the bitlines BL. The shield line control circuit 100 may activate the shield voltage control signal VSC during the charge sharing mode CS and the sensing mode SENS to supply a shield voltage Vsd to the shield lines SDL. Accordingly, in the charge sharing mode CS and the sensing mode SENS, the coupling between the bitlines BL may be prevented.

According to one or more example embodiments, the shield line control circuit 100 may deactivate the shield voltage control signal VSC during the precharge mode PRE. For example, in the precharge mode PRE, the bitlines BL may be fixed to specified voltage(s) and the effect of coupling between the bitlines BL may be minimal. On the other hand, in the precharge mode PRE, when the shield voltage Vsd is supplied to the shield lines SDL and the electrical bridge 10 exists between one of the bitlines BL and one of the shield lines SDL, a leakage current may occur between one of the bitlines BL and one of the shield lines SDL. Accordingly, the shield line control circuit 100 may prevent current leakage by floating the shield lines SDL during the precharge mode PRE.

According to one or more example embodiments, the shield line control circuit 100 may activate the shield voltage control signal VSC while the selected wordline WLi is activated. For example, while the selected wordline WLi may be activated, coupling may occur between the bitlines BL and data errors may occur due to coupling between the bitlines BL. The shield line control circuit 100 may activate the shield voltage control signal VSC while the selected wordline WLi is activated and supply the shield voltage Vsd to the shield lines SDL. Accordingly, while the selected wordline WLi is activated, the coupling between the bitlines BL may be prevented.

According to one or more example embodiments, the shield line control circuit 100 may deactivate the shield voltage control signal VSC while the selected wordline WLi is deactivated. For example, while the selected wordline WLi is deactivated, the bitlines BL may be fixed to specified voltage(s) and the effect of coupling between the bitlines BL may be minimal. On the other hand, while the selected wordline WLi is deactivated, when the shield voltage Vsd is supplied to the shield lines SDL and the electrical bridge 10 exists between one of the bitlines BL and one of the shield lines SDL, a leakage current may occur between one of the bitlines BL and one of the shield lines SDL. Accordingly, the shield line control circuit 100 may prevent current leakage by floating the shield lines SDL while the selected wordline WLi is deactivated.

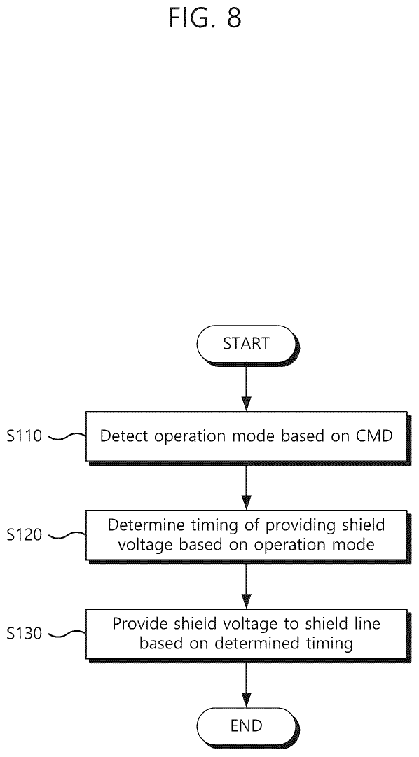

FIG. 8 is a flowchart illustrating a method of controlling a shield voltage of a shield line according to one or more example embodiments. Referring to FIGS. 3 to 8, the shield lines SDL may be disposed between the bitlines BL.

According to one or more example embodiments, in operation S110, the memory device 1200 may detect an operation mode based on a command CMD received from the memory controller 1100. For example, the command decoder 1240 may output a decoded command DC based on the command CMD. The shield line control circuit 100 may detect the current operation mode based on the decoded command DC. As an example, the mode detector 110 may output a mode detection signal MDS including current operation mode information based on the decoded command DC.

According to one or more example embodiments, in operation S120, the memory device 1200 may determine a timing to provide the shield voltage Vsd to the shield lines SDL based on the detected operation mode. For example, the shield line control circuit 100 may determine the timing to provide the shield voltage Vsd based on the current operation mode. As an example, the timing generator 120 may generate the timing signal TS based on the mode detection signal MDS.

According to one or more example embodiments, in operation S130, the memory device 1200 may provide the shield voltage Vsd to the shield lines SDL based on the determined timing. For example, the shield line control circuit 100 may control the switch SW connected between a terminal of the shield voltage Vsd and the shield lines SDL based on the determined timing. As an example, the shield controller 130 may generate the shield voltage control signal VSC based on the timing signal TS. The switch SW may be turned on or turned off depending on the shield voltage control signal VSC. The shield voltage Vsd may be provided to the shield lines SDL according to the shield voltage control signal VSC.

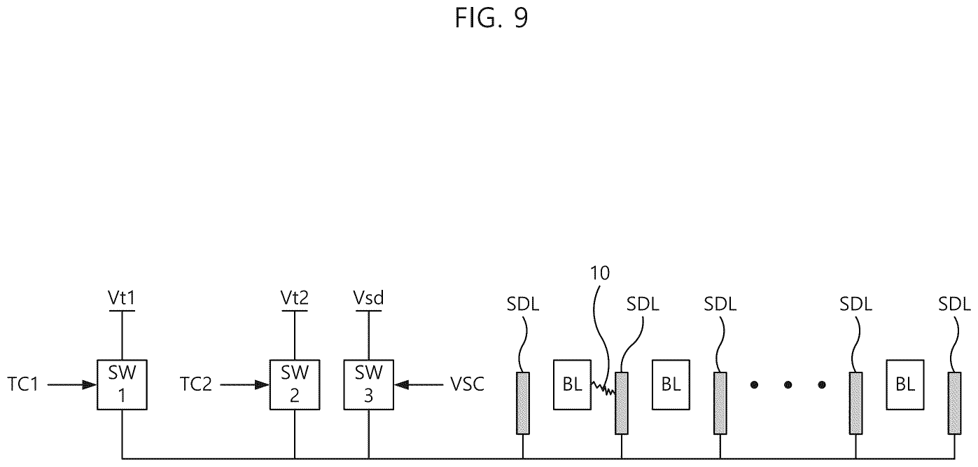

FIG. 9 is a diagram illustrating another example of bitlines and shield lines of FIG. 2. Referring to FIGS. 2 and 9, the bitlines BL may be connected to the memory cell array 1210. Each of shield lines SDL may be alternately arranged between the bitlines BL.

According to one or more example embodiments, the shield lines SDL may be connected to a first test voltage Vt1 through a first switch (or first test switch) SW1. As an example, the first test voltage Vt1 may be a ground voltage. The shield lines SDL may be connected to a second test voltage Vt2 through a second switch (or second test switch) SW2. As an example, the second test voltage Vt2 may be a power supply voltage.

According to one or more example embodiments, the memory device 1200 may detect whether an electrical bridge 10 occurs between one of the bitlines BL and one of the shield lines SDL in a test mode. For example, after the bitlines BL are charged to a specified voltage (for example, a precharge voltage), the memory device 100 may turn on the first switch SW1 to check for current leakage. Alternatively, after the bitlines BL are charged to a specified voltage (for example, a precharge voltage), the memory device 100 may turn on the second switch SW2 to check for current leakage.

According to one or more example embodiments, the first switch SW1 may be turned on or off based on a first test signal TC1. The second switch SW2 may be turned on or off based on a second test signal TC2.

According to one or more example embodiments, the memory device 1200 may detect a location of the electrical bridge 10 in the test mode. For example, after only some of the bitlines BL are charged to a specified voltage (for example, a precharge voltage), the memory device 100 may turn on the first switch SW1 or the second switch SW2 to check for current leakage. The memory device 100 may check for current leakage by turning on the first switch SW1 or the second switch SW2 while changing a bitline charged with the specified voltage.

According to one or more example embodiments, when there is no electrical bridge 10 between one of the bitlines BL and one of the shield lines SDL, the memory device 1200 may generate the shield voltage control signal VSC, such that the shield voltage Vsd may be continuously provided on the shield lines SDL. When there is an electrical bridge 10 between one of the bit lines BL and one of the shield lines SDL, the memory device 1200 may generate the shield voltage control signal VSC such that the shield voltage Vsd may be provided at the timing, for example, as illustrated in FIGS. 5 to 7.

According to one or more example embodiments, the shield lines SDL may be connected to the shield voltage Vsd through a third switch SW3. The third switch SW3 may be turned on or off based on the shield voltage control signal VSC. The third switch SW3 and the shield voltage control signal VSC may have the same configuration and characteristics as the switch SW and the shield voltage control signal VSC of FIG. 3. Accordingly, descriptions of the third switch SW3 and the shield voltage control signal VSC are omitted.

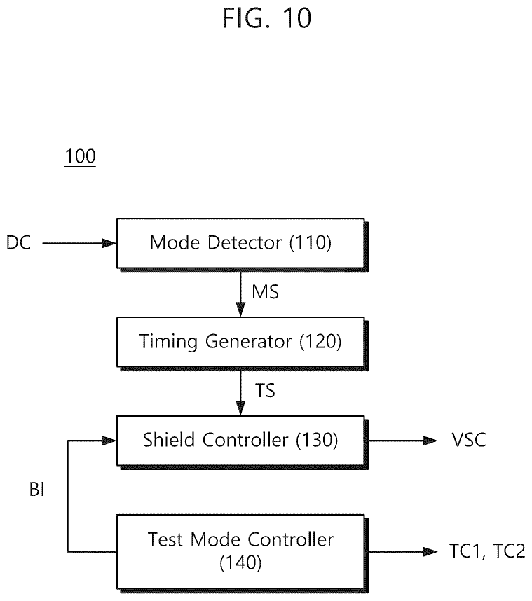

FIG. 10 is a diagram illustrating another example of a shield line control circuit of FIG. 2. Referring to FIGS. 2, 9, and 10, the shield line control circuit 100 may include a mode detector 110, a timing generator 120, a shield controller 130, and a test mode controller 140. The mode detector 110, the timing generator 120, and the shield controller 130 may be the same or similar to the mode detector 110, the timing generator 120, and the shield controller 130 of FIG. 4. Therefore, descriptions of the mode detector 110, the timing generator 120, and the shield controller 130 are omitted.

According to one or more example embodiments, in a test mode for detecting an electrical bridge 10 between one of the bitlines BL and one of the shield lines SDL, the test mode controller 140 may generate a first test signal TC1 and a second test signal TC2. In the test mode, the test mode controller 140 may complementarily generate the first test signal TC1 and the second test signal TC2. For example, when the first test signal TC1 is active, the second test signal TC2 may be inactive. When the first test signal TC1 is inactive, the second test signal TC2 may be active. During a normal operation of the memory device 1200, both the first test signal TC1 and the second test signal TC2 may be deactivated.

According to one or more example embodiments, the test mode controller 140 may store results of a test to detect the electrical bridge 10 between one of the bitlines BL and one of the shield lines SDL. The test mode controller 140 may output a bridge information signal BI indicating presence or absence of the electrical bridge 10 between one of the bitlines BL and one of the shield lines SDL.

According to one or more example embodiments, the shield controller 130 may output the shield voltage control signal VSC based on the bridge information signal BI. For example, when there is no electrical bridge 10 between one of the bitlines BL and one of the shield lines SDL, the bridge information signal BI may have a first level. When there is an electrical bridge 10 between one of the bitlines BL and one of the shield lines SDL, the bridge information signal BI may have a second level.

For example, when the bridge information signal BI is at the first level, the shield controller 130 may generate the shield voltage control signal VSC such that the shield voltage Vsd may be continuously provided to the shield lines SDL. When the bridge information signal BI is at the second level, the shield controller 130 may adjust the timing at which the shield voltage Vsd is provided to the shield lines SDL according to the operation mode during the read operation as in the method of FIG. 8.

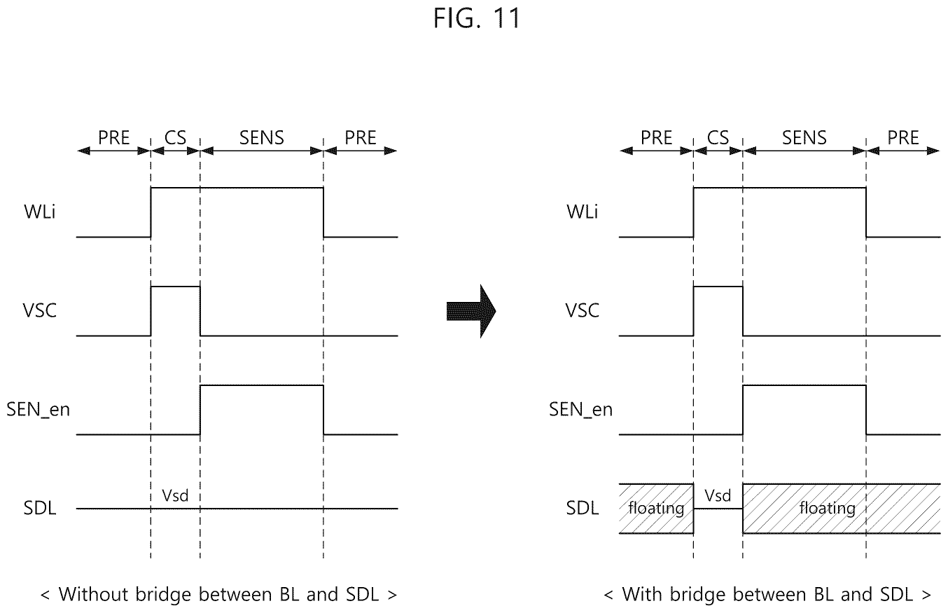

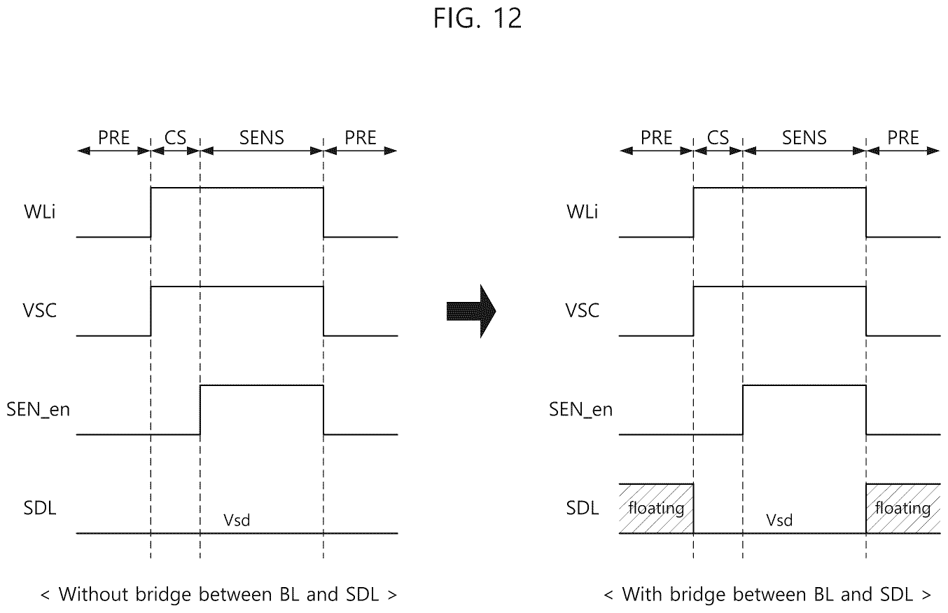

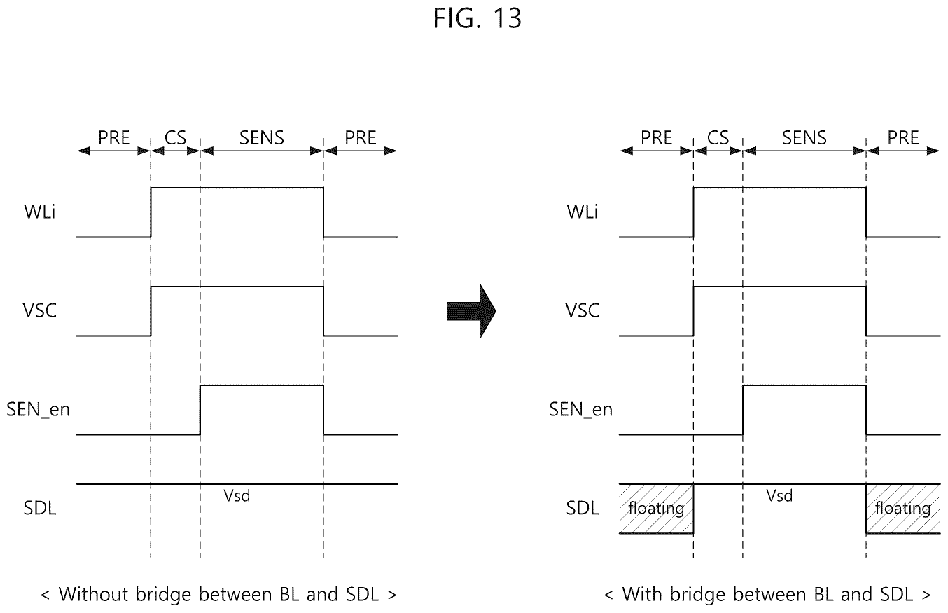

FIG. 11 is a timing diagram illustrating an example of a bitline shielding method using a shield line control circuit of FIG. 10. FIG. 12 is a timing diagram illustrating another example of a bitline shielding method using a shield line control circuit of FIG. 10. FIG. 13 is a timing diagram illustrating another example of a bitline shielding method using a shield line control circuit of FIG. 10. Referring to FIGS. 9 to 13, the shield line control circuit 100 may control a supply timing of the shield voltage Vsd based on the presence or absence of the electrical bridge 10 between one of the bitlines BL and one of the shield lines SDL.

According to one or more example embodiments, in FIG. 11, the shield voltage Vsd may be set to have a voltage equal to the precharge voltage Vpre. In FIGS. 12 and 13, the shield voltage Vsd may be set to have a voltage different from the precharge voltage Vpre. The shield voltage Vsd of FIG. 12 may be set lower than the shield voltage Vsd of FIG. 11. The shield voltage Vsd of FIG. 13 may be set higher than the shield voltage Vsd of FIG. 11.

According to one or more example embodiments, in FIGS. 11 to 13, when there is no electrical bridge 10 between one of the bitlines BL and one of the shield lines SDL, the shield voltage Vsd may continuously be provided to the shield lines SDL. For example, the shield line control circuit 100 may generate the shield voltage control signal VSC to continuously turn on the third switch SW3.

According to one or more example embodiments, the memory device 100 may periodically perform a test to detect whether the electrical bridge 10 occurs between one of the bitlines BL and one of the shield lines SDL. For example, after only some of the bitlines BL are charged to a specified voltage (for example, a precharge voltage), the memory device 100 may turn on the first switch SW1 or the second switch SW2 to check for current leakage. The memory device 100 may check for current leakage by turning on the first switch SW1 or the second switch SW2 while changing a bitline charged with the specified voltage.

According to one or more example embodiments, when the electrical bridge 10 between one of the bitlines BL and one of the shield lines SDL is detected as a result of performing a test to detect the electrical bridge 10, the shield voltage Vsd may be provided to the shield lines SDL according to the determined timing. For example, the shield line control circuit 100 may generate the shield voltage control signal VSC such that the shield voltage Vsd may be provided at the timing, for example, as illustrated in FIGS. 5 to 7.

As described above, when there is no electrical bridge 10 between one of the bitlines BL and one of the shield lines SDL, the memory device 100 may continuously supply the shield voltage Vsd to the shield lines SDL to prevent coupling between the bitlines BL. When the electrical bridge 10 occurs between one of the bitlines BL and one of the shield lines SDL, the memory device 100 may supply the shield voltage Vsd to the shield lines SDL in a specific section to prevent the coupling between the bitlines BL during a read operation. Accordingly, the current leakage between one of the bitlines BL and one of the shield lines SDL may be minimized. For example, the specific section to which the shield voltage Vsd is applied may be determined based on a location at which the electrical bridge 10 between one of the bitlines BL and one of the shield lines SDL is detected in the test mode.

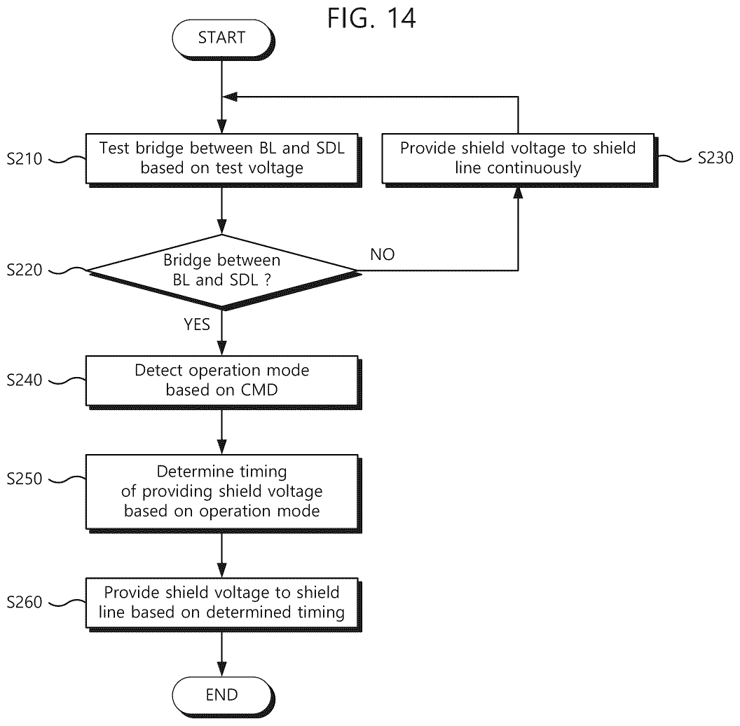

FIG. 14 is a flowchart illustrating a method of controlling a shield voltage of a shield line according to one or more example embodiments. Referring to FIGS. 9 to 14, the shield lines SDL may be disposed between the bitlines BL. The memory device 1200 may provide the shield voltage Vsd to the shield lines SDL.

According to one or more example embodiments, in operation S210, the memory device 1200 may perform a test to detect whether the electrical bridge 10 occurs between one of the bitlines BL and one of the shield lines SDL based on a test voltage. For example, the shield lines SDL may be connected to the first test voltage Vt1 through the first switch SW1. As an example, the first test voltage Vt1 may be a ground voltage. Additionally or alternatively, the shield lines SDL may be connected to the second test voltage Vt2 through the second switch SW3. As an example, the second test voltage Vt2 may be a power supply voltage.

According to one or more example embodiments, the memory device 1200 may detect whether the electrical bridge 10 occurs between one of the bitlines BL and one of the shield lines SDL in the test mode. For example, after the bitlines BL are charged to a specified voltage (for example, a precharge voltage), the memory device 100 may turn on the first switch SW1 to check for current leakage. Alternatively, after the bitlines BL are charged to a specified voltage (for example, a precharge voltage), the memory device 100 may turn on the second switch SW2 to check for current leakage.

According to one or more example embodiments, in operation S220, the memory device 1200 may check whether the electrical bridge 10 exists between one of the bitlines BL and one of the shield lines SDL. When the electrical bridge 10 between one of the bitlines BL and one of the shield lines SDL is not detected, the memory device 1200 may perform operation S230. When the electrical bridge 10 between one of the bitlines BL and one of the shield lines SDL is detected, the memory device 1200 may perform operation S240.

According to one or more example embodiments, in operation S230, the memory device 1200 may continuously provide the shield voltage Vsd to the shield lines SDL. When the electrical bridge 10 between one of the bitlines BL and one of the shield lines SDL is not detected, in order to ensure prevention of coupling between the bitlines BL, the memory device 1200 may continuously provide the shield voltage Vsd to the shield lines SDL.

According to one or more example embodiments, in operation S240, when the electrical bridge 10 between one of the bitlines BL and one of the shield lines SDL is detected, the memory device 1200 may detect an operation mode based on the command CMD received from the memory controller 1100. For example, the command decoder 1240 may output the decoded command DC based on the command CMD. The shield line control circuit 100 may detect the current operation mode based on the decoded command DC. As an example, the mode detector 110 may output the mode detection signal MDS including current operation mode information based on the decoded command DC.

According to one or more example embodiments, in operation S250, the memory device 1200 may determine timing to provide the shield voltage Vsd to the shield lines SDL based on the detected operation mode. For example, the shield line control circuit 100 may determine the timing to provide the shield voltage Vsd based on the current operation mode. As an example, the timing generator 120 may generate the timing signal TS based on the mode detection signal MDS.

According to one or more example embodiments, in operation S260, the memory device 1200 may provide the shield voltage Vsd to the shield lines SDL based on the determined timing. For example, the memory device 1200 may control the third switch SW3 based on the determined timing. The third switch SW3 may have the same configuration as the switch SW of FIG. 3, and thus, the memory device 1200 may control the third switch SW3 connected between a terminal of the shield voltage Vsd and the shield lines SDL based on the determined timing. As an example, the shield controller 130 may generate the shield voltage control signal VSC based on the timing signal TS. The third switch SW3 may be turned on or off at a specified timing according to the shield voltage control signal VSC. The shield voltage Vsd may be provided to the shield lines SDL at the specified timing according to the shield voltage control signal VSC.

Accordingly, when the electrical bridge 10 between one of the bitlines BL and one of the shield lines SDL is detected, the memory device 1200 may supply the shield voltage Vsd in a section which may affect data (e.g., charges stored in memory cells) during the read operation. Thus, coupling between the bitlines BL may be prevented. Additionally, the memory device 1200 may prevent current leakage between one of the bitlines BL and one of the shield lines SDL by blocking the shield voltage Vsd in a section which may not affect data during the read operation.

According to one or more example embodiments of the present disclosure, it may be possible to prevent coupling between the bitlines included in the memory device 1200.

According to one or more example embodiments of the present disclosure, it may be possible to minimize current leakage due to the electrical bridge when an electrical bridge occurs between at least one of the bitlines and at least one of the shield lines.

While the present disclosure has been described with reference to example embodiments thereof, it will be apparent to those of ordinary skill in the art that various changes and modifications may be made thereto without departing from the spirit and scope of the present disclosure as set forth in the following claims and their equivalents.

What is claimed is:

1. A memory device comprising:
a memory cell array including a plurality of memory cells;
bitlines connected to the plurality of memory cells;
shield lines, each being arranged between the bitlines; and
a shield line control circuit configured to control a timing of supplying a shield voltage to the shield lines based on a command received from an outside of the memory device.

2. The memory device of claim 1, wherein the shield line control circuit comprises:
a mode detector configured to generate a mode signal based on the command;
a timing generator configured to generate a timing signal based on the mode signal; and
a shield controller configured to generate a control signal based on the timing signal.

3. The memory device of claim 2, further comprising:
a switch connected between a terminal in which the shield voltage is supplied and the shield lines,
wherein the switch is configured to be turned on or off based on the control signal.

4. The memory device of claim 1, wherein the shield voltage is equal to a precharge voltage of the bitlines, and the shield line control circuit is configured to control the shield voltage to be supplied to the shield lines in a charge sharing mode of a read operation.

5. The memory device of claim 1, wherein the shield voltage is different from a precharge voltage of the bitlines, and the shield line control circuit is configured to control the shield voltage to be supplied to the shield lines in a charge sharing mode and a sensing mode of a read operation.

6. The memory device of claim 1, wherein the shield voltage is different from a precharge voltage of the bitlines, and the shield line control circuit is configured to control the shield voltage to be supplied to the shield lines in response to a selected wordline being activated.

7. A memory device comprising:
a memory cell array including a plurality of memory cells;
bitlines connected to the plurality of memory cells;
shield lines, each being arranged between the bitlines; and
a shield line control circuit configured to control a timing of supplying a shield voltage to the shield lines based on whether an electrical bridge between one of the bitlines and one of the shield lines is detected.

8. The memory device of claim 7, wherein the shield line control circuit is configured to, in response to the electrical bridge between one of the bitlines and one of the shield lines not being detected, control to continuously supply the shield voltage to the shield lines.

9. The memory device of claim 7, wherein the shield line control circuit is configured to, in response to the electrical bridge between one of the bitlines and one of the shield lines being detected, control the timing of supplying the shield voltage to the shield lines based on a command received from an outside of the memory device.

10. The memory device of claim 9, wherein the shield voltage is equal to a precharge voltage of the bitlines, and the shield line control circuit is configured to control the shield voltage to be supplied to the shield lines in a charge sharing mode of a read operation.

11. The memory device of claim 9, wherein the shield voltage is different from a precharge voltage of the bitlines, and the shield line control circuit is configured to control the shield voltage to be supplied to the shield lines in a charge sharing mode and a sensing mode of a read operation.

12. The memory device of claim 9, wherein the shield voltage is different from a precharge voltage of the bitlines, and the shield line control circuit is configured to control the shield voltage to be supplied to the shield lines in response to a selected wordline being activated.

13. The memory device of claim 7, wherein the shield line control circuit comprises:
a test mode controller configured to control a test to detect an occurrence of the electrical bridge between one of the bitlines and one of the shield lines;
a mode detector configured to generate a mode signal based on a command received from an outside of the memory device;
a timing generator configured to generate a timing signal based on the mode signal; and
a shield controller configured to generate a control signal based on the timing signal.

14. The memory device of claim 13, further comprising:
a test switch connected between a test voltage supply terminal and the shield lines,
wherein the test switch is configured to be turned on or off based on a test signal generated by the test mode controller.

15. The memory device of claim 14, wherein the test mode controller is configured to, in a test mode, activate the test signal after the bitlines are charged to a specified voltage.

16. A method of controlling a shield voltage of a memory device, the method comprising:
detecting an occurrence of an electrical bridge between bitlines, connected to a plurality of memory cells, and shield lines, each being disposed between the bitlines;
in response to detecting the occurrence of the electrical bridge, detecting an operation mode based on a command received from an outside of a memory device;
determining a timing of supplying a shield voltage to the shield lines based on the operation mode; and
providing the shield voltage to the shield lines based on the determined timing.

17. The method of claim 16, further comprising:
continuously providing the shield voltage to the shield lines, in response to the occurrence of the electrical bridge not being detected.

18. The method of claim 16, wherein the shield voltage is equal to a precharge voltage of the bitlines, and the determining the timing comprises determining the timing of supplying the shield voltage such that the shield voltage is supplied to the shield lines in a charge sharing mode of a read operation.

19. The method of claim 16, wherein the shield voltage is different from a precharge voltage of the bitlines, and the determining the timing comprises determining the timing of supplying the shield voltage such that the shield voltage is supplied to the shield lines in a charge sharing mode and a sensing mode of a read operation.

20. The method of claim 16, wherein the shield voltage is different from a precharge voltage of the bitlines, and the determining the timing comprises determining the timing of supplying the shield voltage such that the shield voltage is supplied to the shield lines in response to a selected wordline being activated.
